(19) United States
(12) Patent Application Publication
(10) Pub. No.: US 2011/0222710 A1
(43) Pub. Date: Sep. 15, 2011

(54) METHOD AND APPARATUS FOR AUTOMATICALLY REDUCING A VOLUME LEVEL OF AN AUDIO SIGNAL PROVIDED TO A USER

(75) Inventors: Amitava Biswas, El Paso, TX (US); Eric MacDonald, El Paso, TX (US)

(73) Assignee: Board of Regents, The University of Texas System, Austin, TX (US)

(21) Appl. No.: 13/048,109

(22) Filed: Mar. 15, 2011

Related U.S. Application Data
(60) Provisional application No. 61/314,150, filed on Mar. 15, 2010.

(51) Int. Cl. H03G 3/00

(52) U.S. Cl. 381/107

(57) ABSTRACT

The present invention provides a method of automatically reducing a volume level of an audio signal provided to a user. An audio signal is received, the audio signal is provided to the and a current hearing threshold for the user based on one or more psychophysical or electrophysiological responses of the user to the audio signal provided to the user is determined. A temporary threshold shift (TTS) based on the current hearing threshold is determined. If the TTS is above the specified TTS, the volume level of the audio signal provided to the user is automatically reduced.

### CROSS-REFERENCE TO RELATED APPLICATIONS

This patent application is a non-provisional application of U.S. provisional patent application 61/314,150 filed on Mar. 15, 2010 and entitled “Method and Apparatus for Automatically Reducing a Volume Level of an Audio Signal Provided to a User” which is hereby incorporated by reference in its entirety.

### TECHNICAL FIELD OF THE INVENTION

The present invention relates in general to the field of hearing preservation and restoration devices, and more particularly, to a method and apparatus for automatically reducing a volume level of an audio signal provided to a user.

### STATEMENT OF FEDERALLY FUNDED RESEARCH

None.

### INCORPORATION-BY-REFERENCE OF MATERIALS FILED ON COMPACT DISC

None.

### BACKGROUND OF THE INVENTION

Without limiting the scope of the invention, its background is described in connection with rehabilitative hearing preservation and restoration devices.

Loud listening conditions can cause loss of hearing sensitivity and other additional problems such as tinnitus, forgetfulness, depression, hyper-tension, and even panic attacks [1-3]. On Sep. 28, 2009 the European Union announced new rules for MP3 players after a report was issued on Oct. 13, 2008 in Brussels by the Scientific Committee on Emerging and Newly Identified Health Risks. The report stated that one in ten users may be at risk of permanent hearing loss up to 10 million across Europe. The new rules state that mp3 players must have controls to limit volume to protect users' hearing. Currently the prevalent solution is to preset the volume control to a fixed setting. Since that procedure is non-adaptive, that option may result in too much or too little loudness level during subsequent uses.

### SUMMARY OF THE INVENTION

The present invention is a novel design for hearing preservation. Unlike industrial noise dosimeters, the device of the present invention is designed for private use, especially by music lovers who are at risk of hearing damage due to excessively loud and prolonged listening. The device described herein is intended to help individuals manage their own listening condition via continuous monitoring and feedback. The device incorporates a rapid-response automated procedure to assess relative loudness level of music presentation compared to individual threshold of hearing of the user.

The present invention provides a method of automatically reducing a volume level of an audio signal provided to a user. An audio signal is received, the audio signal is provided to the and a current hearing threshold for the user based on one or more psychophysical or electrophysiological responses of the user to the audio signal provided to the user is determined. A temporary threshold shift (TTS) based on the current hearing threshold is determined. If the TTS is above the specified TTS, the volume level of the audio signal provided to the user is automatically reduced.

In addition, the present invention provides a device for automatically reducing a volume level of an audio signal provided to a user. The device includes an audio source, an audio delivery device, one or more psychophysical or electrophysiological sensors, a memory, and a processor. The processor is communicably coupled to the audio source, the audio delivery device, the one or more electrophysiology sensors and the memory. The processor receives an audio signal from the audio source, provides the audio signal to the user via the audio delivery device, determines a current hearing threshold for the user based on one or more psychophysical or electrophysiological responses of the user to the audio signal provided to the user that are received from the one or more psychophysical or electrophysiological sensors, determines a temporary threshold shift based on the current hearing threshold, and automatically reduces the volume level of the audio signal provided to the user whenever the temporary threshold shift exceeds a specified temporary threshold shift.

### BRIEF DESCRIPTION OF THE DRAWINGS

For a more complete understanding of the features and advantages of the present invention, reference is now made to the detailed description of the invention along with the accompanying figures and in which:

FIG. 1 is a flow chart illustrating a method of automatically reducing a volume level of an audio signal provided to a user in accordance with one embodiment of the present invention;

FIG. 2 is a flow chart illustrating a method of automatically reducing a volume level of an audio signal provided to a user in accordance with another embodiment of the present invention;

FIG. 3 is a block diagram of a device for automatically reducing a volume level of an audio signal provided to a user in accordance with another embodiment of the present invention;

FIG. 4 is a schematic diagram showing the basic design of the prototype design of the hearing device in accordance with another embodiment of the present invention;

FIG. 5 is a photograph showing a typical field programmable gate arrays (FPGA) based setup as described in one embodiment of the present invention; and

FIG. 6 is a photograph showing a microcontroller based setup as described in one embodiment of the present invention.

### DETAILED DESCRIPTION OF THE INVENTION

While the making and using of various embodiments of the present invention are discussed in detail below, it should be appreciated that the present invention provides many applicable inventive concepts that can be embodied in a wide variety of specific contexts. The specific embodiments discussed herein are merely illustrative of specific ways to make and use the invention and do not delimit the scope of the invention.

To facilitate the understanding of this invention, a number of terms are defined below. Terms defined herein have meanings as commonly understood by a person of ordinary skill in the areas relevant to the present invention. Terms such as “a”, “an” and “the” are not intended to refer to only a singular entity, but include the general class of which a specific example may be used for illustration. The terminology herein is used to describe specific embodiments of the invention, but their usage does not delimit the invention, except as outlined in the claims.

The device described in the present invention incorporates an automated procedure to detect when the loudness level of sound presentation is detrimental compared to the individual threshold of hearing of the user. As a result of techno-commercial improvements, recent emerging technologies have become available, such as auditory brainstem response (ABR), otoacousticemission (OAE) and expert systems, and are increasingly affordable to individual consumers. For example, now a days, many professional athletes as well as ordinary joggers have started using wristwatch type cardio-logic monitors that can detect electrophysiological performance of the heart through minute electrical signals detectable from the skin surface [5]. Therefore, it is anticipated that although the device presented herein may soon become one of the affordable necessities in view of rapid growth of highly sophisticated audio devices pouring into the consumer market.

One solution to avoid loud music is to use individualized headphones for private listening and also keep the volume control down as far as possible. Nevertheless, the setting for one user may be too low or too high for another user. Even the same user may find a fixed volume control to be unacceptable. As a matter of fact, the volume control was invented in the first place to meet dynamic needs of volume level of the individual user.

Loud listening conditions may cause temporary shift (could be permanent if severe) in hearing threshold that can be detectable via psychophysical tests [1-3]. Therefore, if the audio device is intelligent enough and, it may ask the user verbally at a low enough intensity during a silent interval, a question like, “Hello, can you hear me now? Could you please push the button X?” The device can then determine whether the level was too high and has caused a threshold shift

In case the pleasure of undivided attention to a fine music passage may be affected by such interruptions, alternative electrophysiological measures may be utilized, such as auditory ABR or OAE. ABR involves monitoring minute electrical activity from the skin surface when the auditory system of the individual responds to sound stimuli. Since the user is not required to make any voluntary response, ABR procedure is often useful for very young babies [4]. Since the electrophysiological signal is very weak the sound stimulant is applied over a period of time. The proposed device will utilize the ongoing sound itself as the stimulant and correlate to the electrophysiological response.

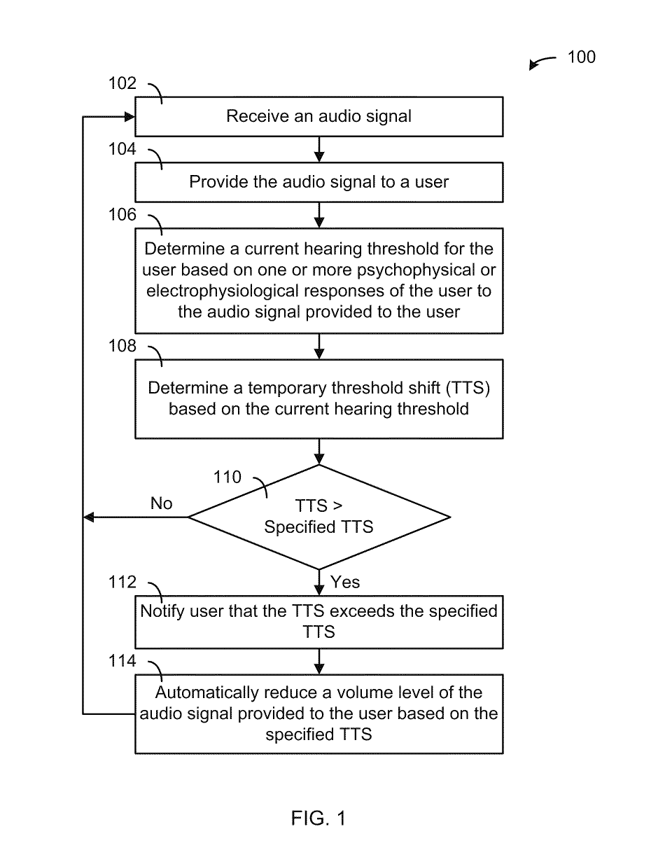

Now referring to FIG. 1, a flow chart illustrating a method 100 of automatically reducing a volume level of an audio signal provided to a user in accordance with one embodiment of the present invention is shown. An audio signal is received in block 102, the audio signal to the user in block 104 and a current hearing threshold for the user based on one or more psychophysical or electrophysiological responses of the user to the audio signal provided to the user is determined in block 106. The one or more psychophysical or electrophysiological responses may include an auditory brainstem response (ABR) of the user, an otoacoustic emission (OAE) or other suitable response from the user. The one or more psychophysical or electrophysiological responses may be received from a microphone or an electrode. In addition, the user can be prompted to perform an action using an audio prompt at or near the hearing threshold of the user. A temporary threshold shift (TTS) based on the current hearing threshold is determined in block 108. If the TTS is not above a specified TTS, as determined in decision block 110, the process loops back to block 102 and the process continues as previously described. The specified TTS may include two or more specified temporary threshold shifts having different magnitudes (e.g., minor shift, large shift, major shift, damaging shift, etc.). If, however, the TTS is above the specified TTS, as determined in decision block 110, the user is notified that the TTS exceeds the specified TTS in block 112 and a volume level of the audio signal provided to the user is automatically reduced in block 114. Note that the notification step in block 112 is not required. Thereafter, the process loops back to block 102 and the process continues as previously described. Note that the determination of the current hearing threshold in block 106 and the subsequent steps can be performed continuously, periodically, randomly or in accordance with a preset schedule. Moreover these steps operate in the background and do not noticeably interrupt, delay or otherwise distort the audio signal provided to the user.

The audio signal can be received from an external source, a live source or an internal source. The audio signal can be provided to the user via a loudspeaker, headphones, headsets, ear buds, in-the-ear speakers, over-the-ear speakers, or noise reducing or canceling devices. The above-described method can be implemented in a personal listening device, a personal audio/visual device, a telecommunications device, a computer, an entertainment device or other suitable device. The personal listening device can be a radio, a tape player, a CD player, a MP3 player, a walkman, or an iPod. The personal audio/visual device can be a DVD player, a television, an iTouch, or an iPad. The telecommunications device can be a phone, a cellular phone, a Wi-Fi phone, a multi-mode phone, or a personal data assistant. The computer can be a notebook computer, a laptop computer, a desktop computer, or a server computer. The entertainment device can be a gaming device, an entertainment system, or a theater system.

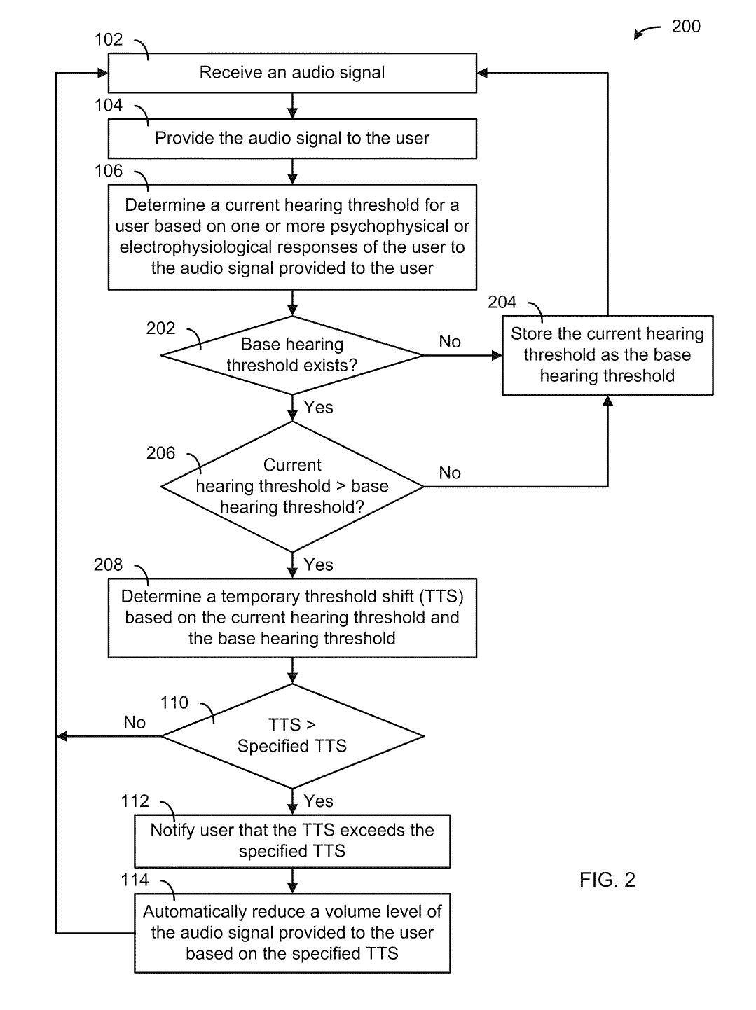

Referring now to FIG. 2, a flow chart illustrating a method 200 of automatically reducing a volume level of an audio signal provided to a user in accordance with another embodiment of the present invention is shown. An audio signal is received in block 102, the audio signal to the user in block 104 and a current hearing threshold for the user based on one or more psychophysical or electrophysiological responses of the user to the audio signal provided to the user is determined in block 106. The one or more psychophysical or electrophysiological responses may include an auditory brainstem response (ABR) of the user, an otoacoustic emission (OAE) or other suitable response from the user. The one or more psychophysical or electrophysiological responses may be received from a microphone or an electrode. In addition, the user can be prompted to perform an action using an audio prompt at or near the hearing threshold of the user. If a base hearing threshold does not exist, as determined in decision block 202, the current hearing threshold is stored as the base hearing threshold in block 204 and the process loops back to block 102. If, however, the base hearing threshold exists, as determined in decision block 202, and the current hearing threshold is less than the base hearing threshold, as determined in decision block 206, the current hearing threshold is stored as the base hearing threshold in block 204 and the process loops back to block 102. If, however, the current hearing threshold is greater than the base hearing threshold, as determined in decision block 206, a temporary threshold shift (TTS) based on the current hearing threshold and the base hearing threshold is determined in block 208. If the TTS is not above a specified TTS, as determined in decision block 110, the process loops back to block 102 and the process continues as previously described. The specified TTS may include two or more specified temporary threshold shifts having different magnitudes (e.g., minor shift, large shift, major shift, damaging shift, etc.). If, however, the TTS is above the specified TTS, as determined in decision block 110, the user is notified that the TTS exceeds the specified TTS in block 112 and a volume level of the audio signal provided to the user is automatically reduced in block 114. Thereafter, the process loops back to block 102 and the process continues as previously described. Note that the determination of the current hearing threshold in block 106 and the subsequent steps can be performed continuously, periodically, randomly or in accordance with a preset schedule. Moreover these steps operate in the background and do not noticeably interrupt, delay or otherwise distort the audio signal provided to the user.

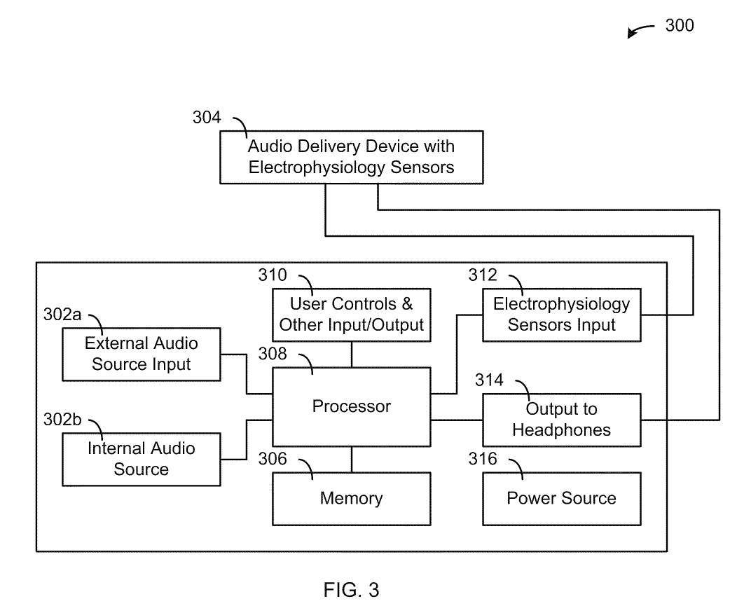

Now referring to FIG. 3, a block diagram of a device 300 for automatically reducing a volume level of an audio signal provided to a user in accordance with another embodiment of the present invention is shown. The device 300 includes an audio source 302, an audio delivery device and one or more psychophysical or electrophysiological sensors (collectively 304), a memory 306, and a processor 308. The processor 308 is communicably coupled to the audio source 302, the audio delivery device and the one or more electrophysiology sensors (collectively 304) and the memory 306. In addition, the processor 308 may also be communicably coupled to user controls and other input/output devices 310, a sensor input or interface 312, an output to the audio delivery device 314. Moreover, the device 300 includes a power supply. The processor 308 receives an audio signal from the audio source 302, provides the audio signal to the user via the audio delivery device 304, determines a current hearing threshold for the user based on one or more psychophysical or electrophysiological responses of the user to the audio signal provided to the user that are received from the one or more psychophysical or electrophysiological sensors 304, determines a temporary threshold shift based on the current hearing threshold, and automatically reduces the volume level of the audio signal provided to the user whenever the temporary threshold shift exceeds a specified temporary threshold shift. The audio source 302 can be an external source 302a, a live source or an internal source 302b. The audio delivery device 304 can be a loudspeaker, headphones, headsets, ear buds, in-the-ear speakers, over-the-ear speakers, or noise reducing or canceling devices. The device 300 can be a personal listening device, a personal audio/visual device, a telecommunications device, a computer, an entertainment device or other suitable device. The personal listening device can be a radio, a tape player, a CD player, a MP3 player, a walkman, or an iPod. The personal audio/visual device can be a DVD player, a television, an iTouch, or an iPad. The telecommunications device can be a phone, a cellular phone, a Wi-Fi phone, a multi-mode phone, or a personal data assistant. The computer can be a notebook computer, a laptop computer, a desktop computer, or a server computer. The entertainment device can be a gaming device, an entertainment system, or a theater system.

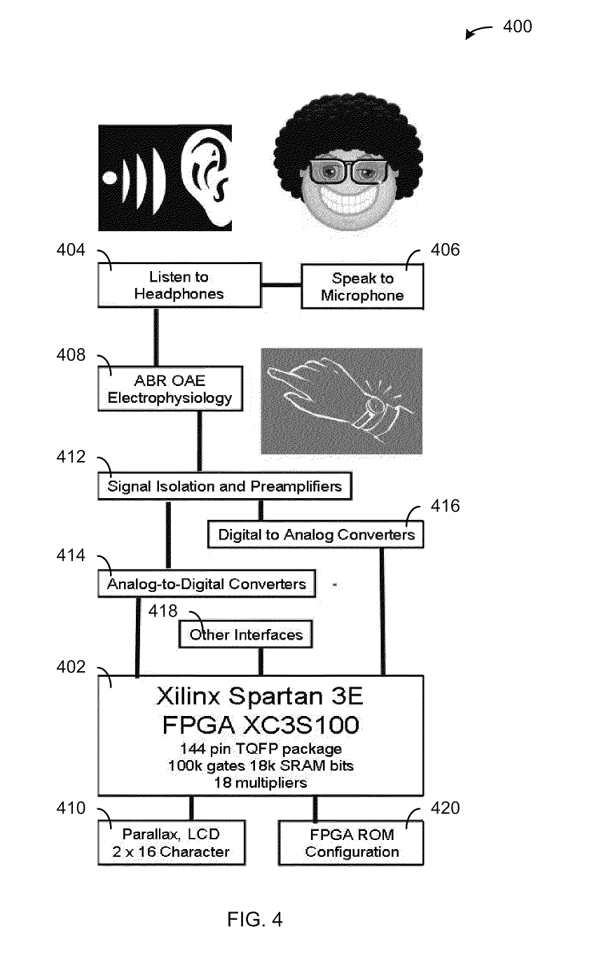

Referring now to FIG. 4 is a schematic diagram showing the basic design of the prototype design of the hearing device 400 in accordance with another embodiment of the present invention is shown. The majority of complexity is confined to an electronic controlling device 402. The controller 402 is configured to accept analog signals and direct audio output to the headphones 404. The FPGA 402 is configured to accept analog signals and direct audio output to the headphones 404. As explained in the previous section, the logic board is programmed to interrogate the user verbally at near threshold of hearing. If the user is unable to respond correctly via the microphone 406, the logic board will alert the user of possible temporary shift in threshold and the likelihood of permanent loss of hearing sensitivity depending upon the severity of the situation. As an alternative to psychophysical assessment, the logic board is equipped with monitoring ABR 408. Another emerging technology is based upon OAE that involves a sensitive microphone listening to minute mechanical activities from the inner ear [6]. The electrodes for ABR and the microphone for OAE (collectively 408) may be integrated with the custom headphone 404. For safety reasons all electrical connections to the user must be isolated properly from the main circuitry. Such arrangements are becoming common as seen in personal cardiac monitors used by joggers [5].

Several approaches for the implementation of the prototype described herein were studied based on the following criteria: (i) ability to sense the level of noise through the user's headsets from a portable music player, and in the ambient surrounding the user close to the user's ears and (ii) portability, ensuring ultra low power for long battery life, rugged and light weight, and low cost.

To implement noise level monitoring in a handheld or wearable device fulfilling these requirements implies the need for a microphone system 406 for monitoring the ambient sound, data acquisition, a parallel audio-in jack for monitoring the magnitude of noise in the headsets 404 and some type of digital circuit capable of processing the input data and responding to both user's input and threshold conditions. The main design decision is the final component, which can be implemented in a variety of ways including a programmable microcontroller 402, a FPGA or as an Application Specific Integrated Circuit (ASIC). Traditionally, a microcontroller 402 provides programmability in a high level language leading to generally shorter development schedules, however, the overhead of this programmability leads to unnecessary increased cost and power consumption of the final product [7-9]. FPGAs and ASICs are generally considered as two steps in the same path: 1) develop the configuration of the FPGA in a hardware description language (HDL), debug and prove functionality with the reconfigurable device and 2) use the resulting hardware description and translate the design into a hard-wired single chip solution. FPGAs are as the name implies programmable in the field allowing for quick turn-around time in the debug and development cycle. However, these devices are prohibitively expensive when considering that low cost is a priority of the monitoring system of the present invention. Once the hardware is developed however, the same design can be translated to hardwired silicon chip (ASIC), which generally provides the lowest unit cost. The challenges with ASICs are that the masks necessary to fabricate a chip can cost over $100,000 as a one-time cost and the time for fabrication is measured in months. In full production, this tooling expense is amortized over the life of the product and the unit cost for ASICs is significantly lower than for the other alternatives. The latency introduced by the fabrication is accounted for in the pipeline and generally is not a problem for high volume production.

The combined approach of developing the product prototype with an FPGA and then subsequently creating an ASIC once the design is finalized is a common strategy in the development of electronics. For the device described herein, a Xilinx Spartan 3E (XC3S100E) Field Programmable Gate Array (FPGA) 402 was selected and is capable of implementing 100K logic gates, 18K SRAM bits and 18 multipliers as required by the data processing algorithm. For communicating with the user, all conditions were reported to the user using a 16×2 character alphanumeric Liquid Crystal Display (LCD) 410 as controlled through a serial port from the FPGA 402. The audio monitoring was performed by a low power wide-band electret compensator microphone (ECM) 406 capable of measuring audio in a frequency range between 20 Hz to 20 KHz. The resulting signal is then amplified through two high performance op-amp gain stages 412 before being delivered to an Analog Devices Analog-to-Digital-Converter (ADC) 414 running at 100K samples per second (Ksps) and with 16 bits of data precision. This digital signal was fed to the FPGA 402. A second parallel analog input was provided through an audio-in headset jack from the user's music device. The logic within the FPGA 402 is capable of detecting the presence of the headsets 404 and selects the correct audio input accordingly. In the case of the audio jack input, the data is reconstructed (possibly at a lower level or with user audio interaction) and sent to audio-out jack to continue to the user's headsets 404 via Digital-to-Analog Converter (DAC) 416. Four buttons, other interfaces 418 or FPGA ROM Configuration 420 are provided to allow for the configuration of the device as well as to allow the user to provide input during hearing tests.

A design of a protective system is presented hereinabove that utilizes emerging technologies of ABR OAE and expert system. There are some audio devices available in the market that can be set to limit the sound output to a lower volume, however these devices are not intelligent enough to adapt to physiological responses of individual listeners automatically. The proposed design utilizes the concept of temporary threshold shift to alert the user of unsafe listening conditions. The temporary threshold shift is estimated via conventional psychophysics or electrophysiology, such as ABR or OAE type of monitoring depending on user choice or convenience. Unlike industrial noise dosimeters, the device of the present invention may be applicable for private home use, especially by music lovers who are at risk of premature hearing damage due to self-administered excessively loud and prolonged listening conditions. Basically, it is intended to help individuals manage their own listening condition via continuous monitoring and feedback.

As the listener listens to his or her favorite music, the onboard microcomputer utilizes the ongoing music output itself as the stimulant and monitors various psychophysical or electrophysiological responses via an expert system type analysis to estimate whether the listener is exceeding safe listening conditions. The device features highly compact portability for harsh environments, particularly in the hands of young users. Two approaches are disclosed hereinabove: one based on microcontrollers and the other based on FPGAs. The simplicity of the user interface ensures that ordinary consumers would be able to use the device with minimal training or practice. The device may be very useful to ensure safe listening conditions under dynamic and unusual environments, as well as for regular consumers who may tend to exceed safe listening levels for prolonged periods, especially young people

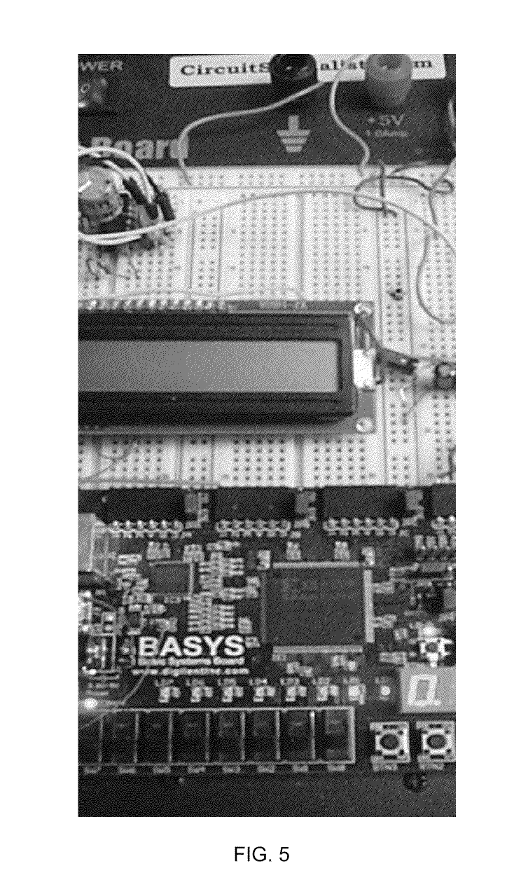

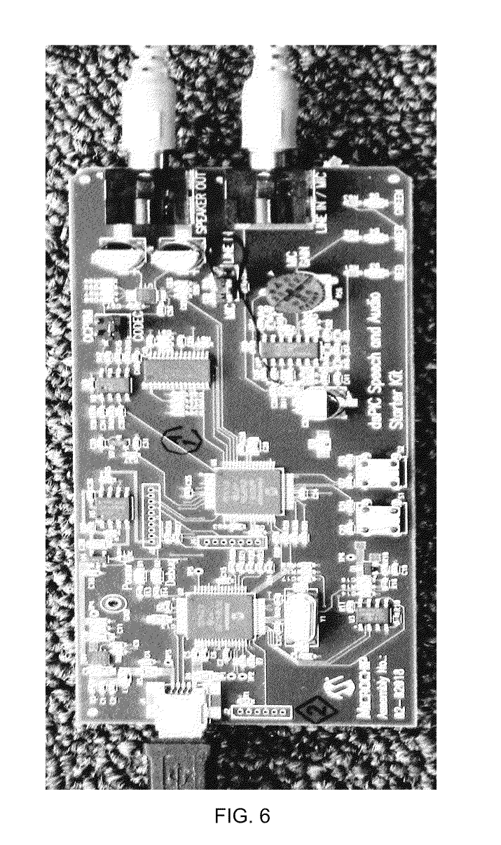

For example, FIG. 5 is a photograph showing a typical field programmable gate arrays (FPGA) based setup as described in one embodiment of the present invention, and FIG. 6 is a photograph showing a microcontroller based setup as described in one embodiment of the present invention. These two design approaches described above include one based on Microchip microcontrollers and the other based on Xilinx field programmable gate arrays (FPGAs). The simplicity of the user interface ensures that ordinary consumers would be able to use the device with minimal training or practice.

It will be understood that particular embodiments described herein are shown by way of illustration and not as limitations of the invention. The principal features of this invention can be employed in various embodiments without departing from the scope of the invention. Those skilled in the art will recognize, or be able to ascertain using no more than routine experimentation, numerous equivalents to the specific procedures described herein. Such equivalents are considered to be within the scope of this invention and are covered by the claims.

All publications and patent applications mentioned in the specification are indicative of the level of skill of those skilled in the art to which this invention pertains. All publications and patent applications are herein incorporated by reference to the same extent as if each individual publication or patent application was specifically and individually indicated to be incorporated by reference.

The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or the alternatives are mutually exclusive, although the disclosure supports a definition that refers to only alternatives and “and/or.” Throughout this application, the term “about” is used to indicate that a value includes the inherent variation of error for the device, the method being employed to determine the value, or the variation that exists among the study subjects.

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, MB, BBC, AAABCCCC, CBBAAA, CABABB, and so forth. The skilled artisan will understand that typically there is no limit on the number of items or terms in any combination, unless otherwise apparent from the context.

All of the methods disclosed and claimed herein can be made and executed without undue experimentation in light of the present disclosure. While the methods of this invention have been described in terms of preferred embodiments, it will be apparent to those of skill in the art that variations may be applied to the compositions and/or methods and in the steps or in the sequence of steps of the method described herein without departing from the concept, spirit and scope of the invention. All such similar substitutes and modifications apparent to those skilled in the art are deemed to be within the spirit, scope and concept of the invention as defined by the appended claims.

### REFERENCES

[1] Miller J D (1974) Effects of noise on people. J Acoust Soc Am 56:729-764
[2] Field J M (1993) Effect of personal and situational variables upon noise annoyance in residential areas. J Acoust Soc Am 93: 2753-2763.
[3] Drake-Lee A B (1992) Beyond music: auditory temporary threshold shift in rock musicians after a heavy concert. J Royal Soc Med 85:617-619
[4] David A et al (1997) A critical review of the role of neonatal hearing screening in the detection of congenital hearing impairment. Health Technol Assess 10:1-176
[5] Moore S M et al (2003) Predictors of women's exercise maintenance after cardiac rehabilitation. J Cardiopulm Rehabil 23:40-49
[6] Kemp D T (1978) Stimulated acoustic emissions from within the human auditory system. J Acoust Soc Am 64:1386-1391
[7] MPLAB Starter Kit for dsPIC DSCs at http://wwwmicrochip.com
[8] BASYS system board at http://www.digilent.com
[9] Xilinx FPGA data at http://www.xilinx.com

What is claimed is:

1. A method of automatically reducing a volume level of an audio signal provided to a user comprising the steps of:
receiving an audio signal;
providing the audio signal to the user;
determining a current hearing threshold for the user based on one or more psychophysical or electrophysiological responses of the user to the audio signal provided to the user;
determining a temporary threshold shift based on the current hearing threshold; and
automatically reducing the volume level of the audio signal provided to the user whenever the temporary threshold shift exceeds a specified temporary threshold shift.

2. The method as recited in claim 1, wherein the one or more psychophysical or electrophysiological responses comprise:
an auditory brainstem response of the user; or
an otoacoustic emission from the user.

3. The method as recited in claim 1, further comprising the step of prompting the user to perform an action using an audio prompt at or near the hearing threshold of the user.

4. The method as recited in claim 1, further comprising the step of notifying the user that the temporary threshold shift exceeds the specified temporary threshold shift.

5. The method as recited in claim 1, further comprising the step of storing the current hearing threshold as a base hearing threshold, and wherein the temporary threshold shift is based on the current hearing threshold and the base hearing threshold.

6. The method as recited in claim 1, further comprising the step of receiving the one or more psychophysical or electrophysiological responses from a microphone or an electrode.

7. The method as recited in claim 1, wherein the specified temporary threshold shift comprises two or more specified temporary threshold shifts having different magnitudes.

8. The method as recited in claim 1, wherein:
the audio signal is received from an external source, a live source or an internal source; and
the audio signal is provided to the user via a loudspeaker, headphones, headsets, ear buds, in-the-ear speakers, over-the-ear speakers, or noise reducing or canceling devices.

9. The method as recited in claim 1, wherein the method is implemented in a personal listening device, a personal audio/visual device, a telecommunications device, a computer, or an entertainment device.

10. The method as recited in claim 9, wherein:
the personal listening device comprises a radio, a tape player, a CD player, a MP3 player, a walkman, or an iPod;
the personal audio/visual device comprises a DVD player, a television, an iTouch, or an iPad;
the telecommunications device comprises a phone, a cellular phone, a Wi-Fi phone, a multi-mode phone, or a personal data assistant;
the computer comprises a notebook computer, a laptop computer, a desktop computer, or a server computer; or
the entertainment device comprises a gaming device, an entertainment system, or a theater system.

11. A device that automatically reduces a volume level of an audio signal provided to a user, the device comprising:
an audio source;
an audio delivery device;
one or more psychophysical or electrophysiological sensors;
a memory; and
a processor communicably coupled to the audio source, the audio delivery device, the one or more electrophysiology sensors and the memory, wherein the processor receives an audio signal from the audio source, provides the audio signal to the user via the audio delivery device, determines a current hearing threshold for the user based on one or more psychophysical or electrophysiological responses of the user to the audio signal provided to the user that are received from the one or more psychophysical or electrophysiological sensors, determines a temporary threshold shift based on the current hearing threshold, and automatically reduces the volume level of the audio signal provided to the user whenever the temporary threshold shift exceeds a specified temporary threshold shift.

12. The device as recited in claim 11, wherein:
the audio source comprises an external source, a live source or an internal source; and
the audio delivery device comprises a loudspeaker, headphones, headsets, ear buds, in-the-ear speakers, over-the-ear speakers, or noise reducing or canceling devices; and
the device comprises a personal listening device, a personal audio/visual device, a telecommunications device, a computer, or an entertainment device.

13. The device as recited in claim 12, wherein:
the personal listening device comprises a radio, a tape player, a CD player, a MP3 player, a walkman, or an iPod;
the personal audio/visual device comprises a DVD player, a television, an iTouch, or an iPad;
the telecommunications device comprises, a phone, a cellular phone, a Wi-Fi phone, a multi-mode phone, or a personal data assistant;
the computer comprises a notebook computer, a laptop computer, a desktop computer, or a server computer; or
the entertainment device comprises a gaming device, an entertainment system, or a theater system.

14. The device as recited in claim 11, further comprising one or more user controls, an interface or input/output device communicably coupled to the processor.

15. The device as recited in claim 11, wherein the one or more psychophysical or electrophysiological responses comprise:
an auditory brainstem response of the user; or
an otoacoustic emission from the user.

16. The device as recited in claim 11, wherein the processor further prompts the user to perform an action using an audio prompt at or near the hearing threshold of the user;

17. The device as recited in claim 11, wherein the processor further notifies the user that the temporary threshold shift exceeds the specified temporary threshold shift.

18. The device as recited in claim 11, wherein the processor further stores the current hearing threshold as a base hearing threshold, and wherein the temporary threshold shift is based on the current hearing threshold and the base hearing threshold.

19. The device as recited in claim 11, wherein the one or more psychophysical or electrophysiological sensors comprise a microphone or an electrode.

20. The device as recited in claim 11, wherein the specified temporary threshold shift comprises two or more specified temporary threshold shifts having different magnitudes.
